(19) United States
(12) Patent Application Publication
(10) Pub. No.: US 2011/0210748 A1
(43) Pub. Date: Sep. 1, 2011

(54) SEMICONDUCTOR INTEGRATED CIRCUIT AND ELECTRONIC INFORMATION DEVICE

(75) Inventors: Ryota NISHIKAWA, Shiga (JP); Hideyuki Kabuo, Kyoto (JP)

(73) Assignee: PANASONIC CORPORATION, OSAKA (JP)

(21) Appl. No.: 13/103,753

(22) Filed: May 9, 2011

Related U.S. Application Data
(63) Continuation of application No. PCT/JP2009/003326, filed on Jul. 15, 2009.

(30) Foreign Application Priority Data
Jan. 16, 2009 (JP) 2009-007532

(51) Int. Cl. G01R 31/02

(52) U.S. Cl. 324/537

(57) ABSTRACT

A semiconductor integrated circuit and an electronic information device each of which can detect a fault at one of control signals of tristate gates with a smaller area than conventional ones and without reducing the speed of normal operation, by providing a fault detector using tristate gates.

### CROSS-REFERENCE TO RELATED APPLICATION

This is a continuation of PCT International Application PCT/JP2009/003326 filed on Jul. 15, 2009, which claims priority to Japanese Patent Application No. 2009-007532 filed on Jan. 16, 2009. The disclosures of these applications including the specifications, the drawings, and the claims are hereby incorporated by reference in its entirety.

### BACKGROUND

The present disclosure relates to the field of semiconductor integrated circuits (ICs) and to the technical field of fault detection of electronic information devices.

In recent years, performance of electronic information devices has drastically improved, and accordingly, higher performance has been required of semiconductor IC devices used therein. A technique for improving performance of a semiconductor IC is one in which the IC is configured using tristate gates. While usage of tristate gates allows the speed of an IC to be increased, a problem exists in that a fault at a control signal of a tristate gate cannot be detected by scan testing.

As a technique for detecting control signals of tristate gates by scan testing, one conventional technique has been suggested in which control signals are input to a stuck-at fault detector in order to detect a stuck-at fault (e.g., Patent Document 1). Moreover, a technique has been suggested in which a supplementary circuit is provided at an output portion driven by tristate gates in order to detect a stuck-at fault (e.g., Patent Document 2).

The referenced Patent Documents are as follows:
Patent Document 1: Japanese Utility Model Publication No. H01-010677 (p. 188, FIG. 1)
Patent Document 2: Japanese Patent Publication No. H11-052019 (FIG. 1)

### SUMMARY

However, the stuck-at fault detector suggested in Patent Document 1 is problematic in that although the detector is required only for testing and is not required for normal operation, the circuit size is large. In addition, the supplementary circuit suggested in Patent Document 2 is provided at an output during normal operation, and is problematic in that the operational speed is affected in a circuit in which a higher speed is demanded.

The present invention was made in view of the foregoing, and an object of the present invention is to provide a circuit in which an increase in the circuit area for testing can be reduced without disturbing high speed operation of tristate gates.

In order to solve these problems, the present invention suggests a circuit using tristate gates.

Specifically, according to one example embodiment, a semiconductor integrated circuit includes a fault detector configured to receive control signals which are input to control terminals of corresponding tristate gates, and a test enable signal, and configured to invert an output signal when one of the control signals is inverted due to a fault at the one of the control signals, where the fault detector includes a set of tristate gates different from the corresponding tristate gates.

According to one example embodiment, in the semiconductor integrated circuit, the fault detector includes the n tristate gates, where n is an integer greater than or equal to 3, configured to respectively receive the n control signals, a control terminal of a k-th one, where 0≦k≦n, of the set of the tristate gates is configured to receive a k-th one of the control signals, a data terminal of the k-th one, where 0≦k≦(n−1), of the set of the tristate gates is configured to receive a (k+1)-th one of the control signals, a data terminal of the n-th one of the set of the tristate gates is configured to receive a 0-th one of the control signals, outputs of the n tristate gates are coupled at a same node, and a transistor configured to pull up or pull down the output signal under a predetermined condition is coupled to the same node.

According to one example embodiment, in the semiconductor integrated circuit, the fault detector is configured to pull up the output signal to 1 or to pull down the output signal to 0 when a plurality of the tristate gates drive the same node.

According to one example embodiment, in the fault detector of the semiconductor integrated circuit, a size of an NMOS transistor which drives the same node is larger than a size of a PMOS transistor which drives the same node, among transistors included in the set of tristate gates.

According to one example embodiment, in the fault detector of the semiconductor integrated circuit, when a PMOS transistor and an NMOS transistor included in the plurality of the tristate gates simultaneously drive the same node, a size ratio between the PMOS transistor and the NMOS transistor is adjusted so that drive operation by the PMOS transistor is dominant.

According to one example embodiment, in the semiconductor integrated circuit, each of the set of the tristate gates is formed by a tristate buffer.

According to one example embodiment, in the semiconductor integrated circuit, each of the set of the tristate gates is formed by a tristate inverter.

According to one example embodiment, an electronic information device includes the semiconductor integrated circuit, and an electronic component configured to communicate with the semiconductor integrated circuit, where the semiconductor integrated circuit includes a communication circuit including n tristate gates, where n is an integer greater than or equal to 3, the communication circuit communicates with the electronic component, control signals of the tristate gates are input to the fault detector, and signals of the communication circuit are short-circuited outside the semiconductor integrated circuit, and are input to the electronic component.

According to the present invention, the tristate gates used in the semiconductor integrated circuit can detect a fault at a control signal without affecting the operational speed and with reduction in an increase in the circuit area for testing.

### BRIEF DESCRIPTION OF THE DRAWINGS

FIG. 1 is a diagram illustrating a configuration of a semiconductor IC according to the first embodiment.

FIG. 2 is a diagram illustrating a circuit configuration of the fault detector.

FIG. 3 is a table of patterns for fault detection.

FIG. 4 is a diagram illustrating an example configuration of the tristate buffers.

FIG. 5 is a diagram illustrating another example configuration of the tristate buffers.

FIG. 6 is a diagram illustrating a circuit configuration of a fault detector according to the second embodiment.

FIG. 7 is a diagram illustrating a circuit configuration of a fault detector according to the second embodiment.

FIG. 8 is a table of patterns for fault detection.

FIG. 9 is a diagram illustrating a circuit configuration of a fault detector according to the third embodiment.

FIG. 10 is a table of patterns for fault detection.

FIG. 11 is a diagram illustrating a configuration of a conventional fault detector.

FIG. 12 is a diagram illustrating a circuit configuration of a fault detector according to the fourth embodiment.

FIG. 13 is a diagram illustrating an example configuration of the tristate inverters.

FIG. 14 is a diagram illustrating another example configuration of the tristate inverters.

FIG. 15 is a diagram illustrating a configuration of an electronic information device according to the fifth embodiment.

FIG. 16 is a diagram illustrating a configuration of an electronic information device according to the fifth embodiment.

### DETAILED DESCRIPTION

Example embodiments of the present invention with respect to a semiconductor IC and an electronic information device will be described below in detail with reference to the drawings.

### First Embodiment

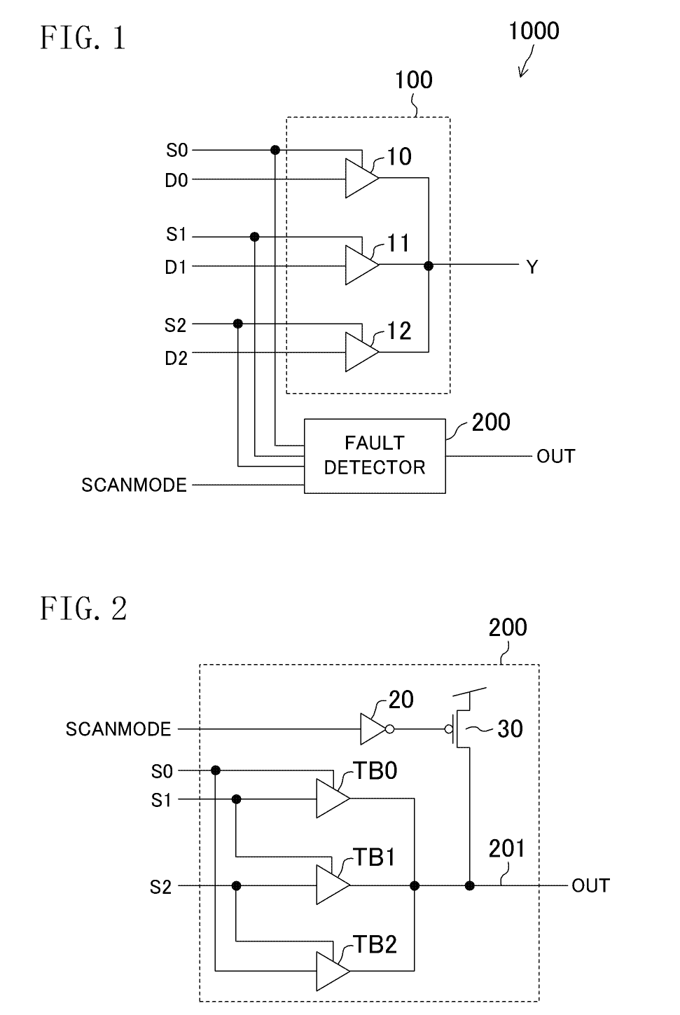

A configuration of a semiconductor IC 1000 according to the first embodiment is shown in FIG. 1. The semiconductor IC 1000 includes a selector circuit 100 and a fault detector 200.

The selector circuit 100 includes tristate gates 10, 11, and 12. Data terminals of the tristate gates 10, 11, and 12 respectively receive data signals D0, D1, and D2, and control terminals thereof respectively receive control signals S0, S1, and S2. Outputs of the tristate gates 10, 11, and 12 are short-circuited at an output terminal Y of the selector circuit 100.

Such a configuration of the selector circuit 100 using the tristate gates 10, 11, and 12 requires a control operation so as to set only one of the control signals S0, S1, and S2 to “1” and the others to “0.” A case where a stuck-at fault occurs at one of the control signals S0, S1, and S2 during such control will be discussed below. If a stuck-at-0 fault occurs, none of the tristate gates drive the output, thereby causing the output to float, and thus to be undetermined; therefore, faults cannot be detected. Meanwhile, if a stuck-at-1 fault occurs, more than one tristate gates drive the output, and thus a same set of input data result in a same output as that during normal operation, thereby causing faults to be undetectable, while a different set of input data cause the output to be undetermined, thereby causing faults to be undetectable.

The semiconductor IC 1000 of this embodiment can detect a fault at a control signal which usually cannot be detected as described above, by providing the fault detector 200. The fault detector 200 receives the control signals S0, S1, and S2 and a mode signal SCANMODE, and outputs a test enable signal OUT.

A circuit configuration of the fault detector 200 according to the first embodiment is shown in FIG. 2. The fault detector 200 includes tristate buffers TB0, TB1, and TB2, an inverter 20, and a PMOS transistor 30.

The control signal S0 is input to a control terminal of the tristate buffer TB0 and to a data terminal of the tristate buffer TB2. The control signal S1 is input to a control terminal of the tristate buffer TB1 and to a data terminal of the tristate buffer TB0. The control signal S2 is input to a control terminal of the tristate buffer TB2 and to a data terminal of the tristate buffer TB1. The output terminals of the tristate buffers TB0, TB1, and TB2 are short-circuited at an output terminal 201 of the fault detector 200.

The mode signal SCANMODE is fixed to “0” during normal operation, and transitions to “1” only when a test is performed. The mode signal SCANMODE is input to the input terminal of the inverter 20. The output terminal of the inverter 20 is coupled to the gate of the PMOS transistor 30. The source of the PMOS transistor 30 is coupled to a power terminal, and the drain thereof is coupled to the output terminal 201. The PMOS transistor 30 is adjusted to have lower drive capability as compared to the transistors included in the tristate buffers TB0, TB1, and TB2.

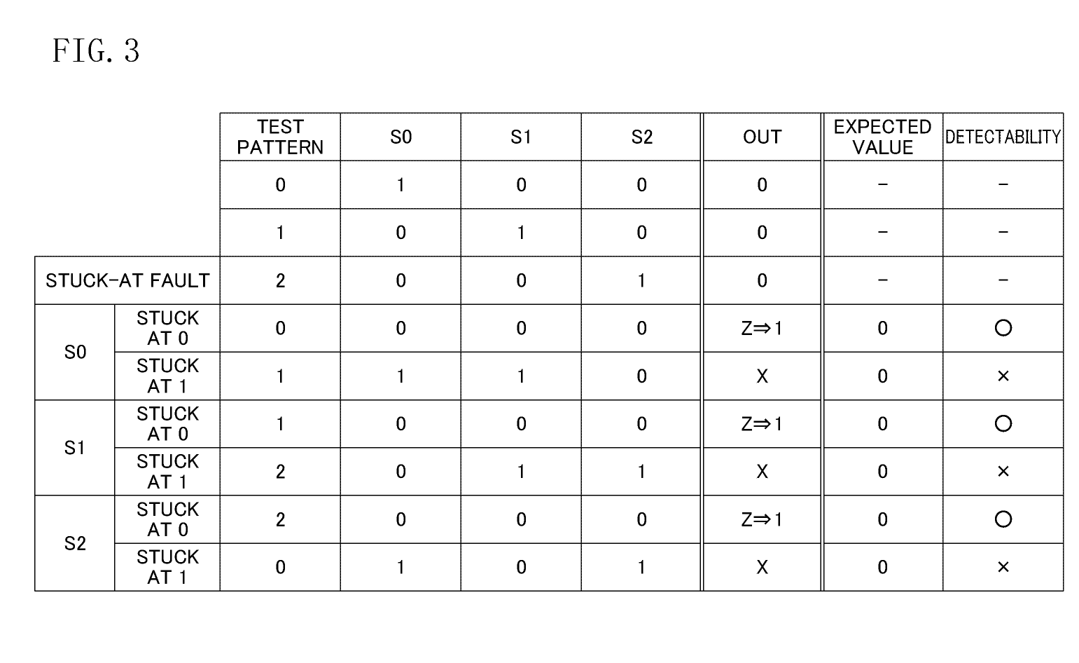

FIG. 3 is a table for detection of stuck-at faults at the control signals S0, S1, and S2 under the configuration of FIG. 2. Taking into account the limitation on the control signals S0, S1, and S2, the table of FIG. 3 has three test patterns 0, 1, and 2 for detecting a stuck-at fault.

Detection of a stuck-at-0 fault at the control signal S0 is performed by inputting a test pattern 0, which causes a logical “0” to be output as the output signal OUT during normal operation. This is the expected value for the case.

If a stuck-at-0 fault occurs at the control signal S0, the control signals S0, S1, and S2 input to the fault detector 200 of FIG. 2 are all “0,” and thus none of the tristate buffers TB0, TB1, and TB2 drive the output terminal 201. In this case, the PMOS transistor 30 fixes the value of the output terminal 201 at “1,” thereby causing the output signal OUT to differ from the expected value of “0.” Accordingly, an occurrence of a stuck-at-0 fault at the control signal S0 can be detected. Likewise, a stuck-at-0 fault at each of the control signals S1 and S2 can be detected.

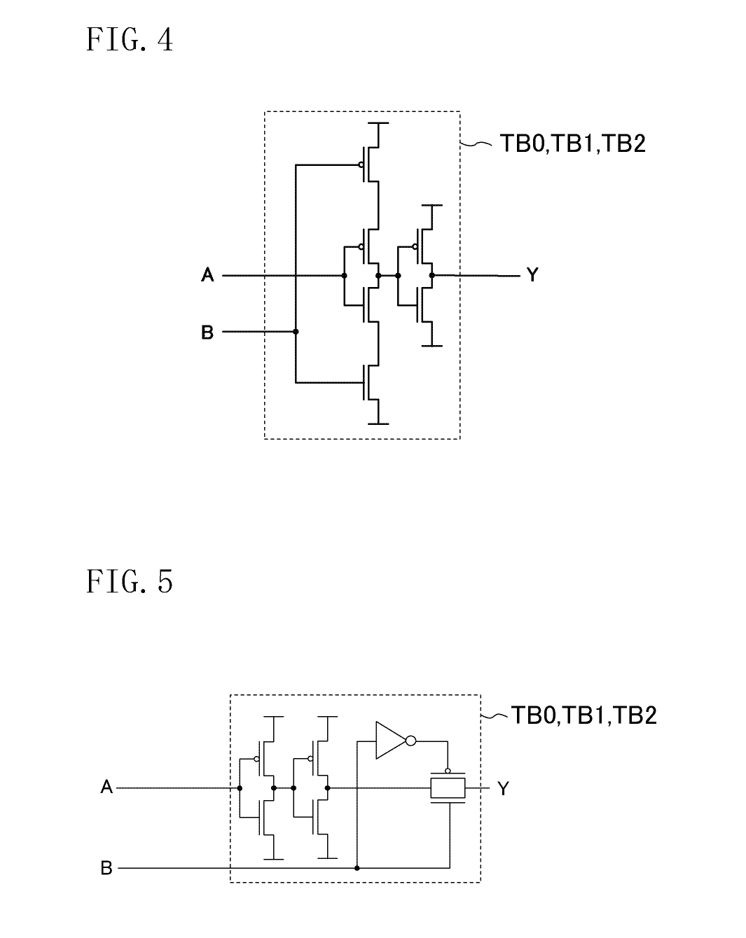

FIGS. 4 and 5 each illustrate an example of an internal configuration of each of the tristate buffers TB0, TB1, and TB2 included in the fault detector 200. The internal configurations are illustrated merely by way of example, and any element which can transition between three states can be used to implement the fault detector 200.

### Second Embodiment

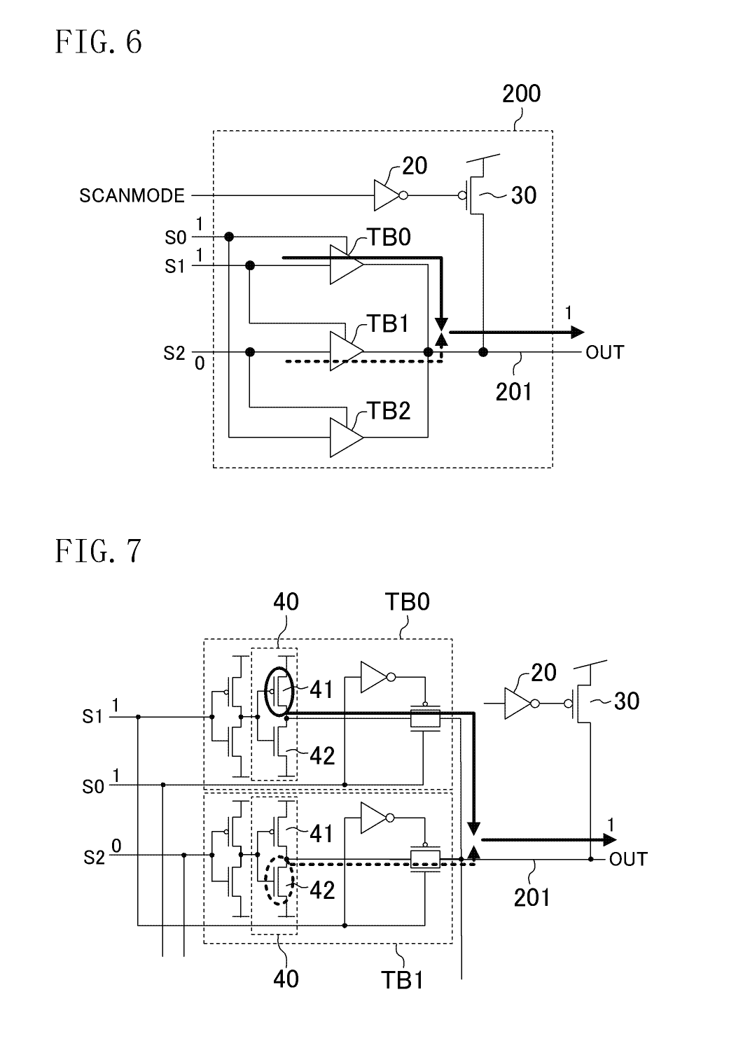

FIG. 6 illustrates a configuration of a fault detector 200 according to the second embodiment. The configuration of the fault detector 200 of FIG. 6 is equivalent to that of FIG. 2. In this embodiment, either or both of the drive capability of each of the tristate buffers TB0, TB1, and TB2 and the PMOS transistor 30 are adjusted so that when (1) two of the input control signals S0, S1, and S2 (here, S0 and S1) are “1” at the same time, and (2) the input signals to the data terminals of the tristate buffers (here, TB0 and TB1) whose control terminals receive the two control signals (here, S0 and S1) are respectively “0” (corresponding to TB1) and “1” (corresponding to TB0), the output signal OUT of the fault detector 200 is “1.”

FIG. 6 illustrates an example where a logical “1” is input as each of the control signals S0 and S1, and a logical “0” is input as the control signal S2. In this case, the tristate buffers TB0 and TB1 are activated, and then, both the value (here “1”) of the input signal S1 to the data terminal of the tristate buffer TB0 and the value (here “0”) of the input signal S2 to the data terminal of the tristate buffer TB1 drive the output terminal 201; thus, the values “1” and “0” conflict with each other. In such a case, in the fault detector 200 of this embodiment, the tristate buffer TB0 which drives the output terminal 201 with “1” is dominant in driving the output terminal 201, and thus a logical “1” is output as the output signal OUT.

FIG. 7 provides a more detailed depiction of the tristate buffers TB0 and TB1 of FIG. 6, each of which is configured using the circuit of FIG. 5. In this case, the output terminal 201 of the fault detector 200 is driven by the inverters 40 of the tristate buffers TB0 and TB1. If a logical “1” is input as each of the control signals S0 and S1 as described above, specifically as shown in FIG. 7, both a PMOS transistor 41 of the inverter 40 of the tristate buffer TB0 and an NMOS transistor 42 of the inverter 40 of the tristate buffer TB1 drive the output terminal 201. In this regard, the size ratio between the PMOS transistor 41 of the inverter 40 of the tristate buffer TB0 and the NMOS transistor 42 of the inverter 40 of the tristate buffer TB1 is designed so that the output signal OUT is set to “1” when the signal values conflict with each other. Note that since symmetrical configuration can be used for the tristate buffers TB0, TB1, and TB2, a size ratio obtained by adjusting between the PMOS transistor 41 and the NMOS transistor 42 of the inverter 40 of the tristate buffer TB0 may be applied to the other tristate buffers TB1 and TB2; or the size ratio may be individually adjusted for the tristate buffers TB0, TB1, and TB2.

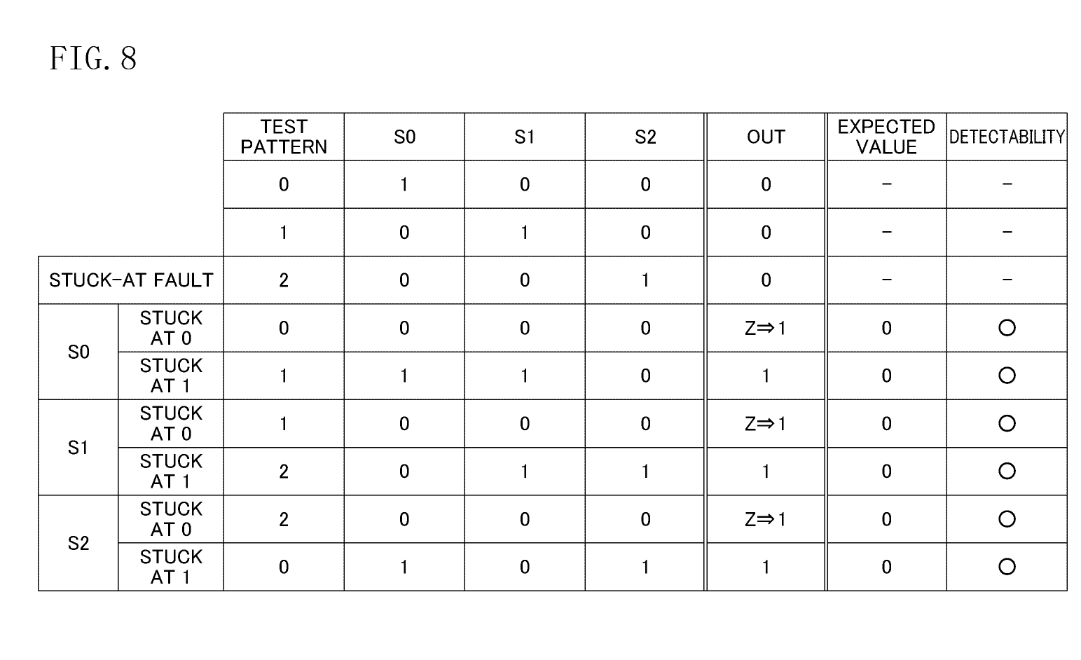

With such a configuration, a stuck-at-1 fault at the control signals S0, S1, and S2 can also be detected. FIG. 8 is a table for detection of stuck-at-1 faults. Referring to FIG. 8, detection of a stuck-at-1 fault at the control signal S0 is performed by inputting a test pattern 1, which causes a logical “0” to be output as the output signal OUT during normal operation. This is the expected value for the case. If a stuck-at-1 fault occurs, a logical “1” is input as each of the control signals S0 and S1, and a logical “0” is input as the control signal S2. As described above, the fault detector 200 of FIG. 6 outputs a logical “1” as the output signal OUT in this case. This value is in conflict with the expected value of “0,” thereby allowing a stuck-at-1 fault at the control signal S0 to be detected.

Likewise, FIG. 8 shows that a stuck-at-1 fault at the control signals S1 and S2 can also be detected.

While the description above has been directed to a case in which the size ratio between the PMOS transistor 41 and the NMOS transistor 42 is adjusted so that the output signal OUT is set to “1” when the signal values conflict with each other, the size ratio between the PMOS transistor 41 and the NMOS transistor 42 may be adjusted so that the output signal OUT is set to “0” when the signal values conflict with each other (for example, the size of the NMOS transistor 42 is made larger than that of the PMOS transistor 41). Also, in this case, symmetrical configuration can be used for the tristate buffers TB0, TB1, and TB2; therefore, a size ratio obtained by adjusting between the PMOS transistor 41 and the NMOS transistor 42 of the inverter 40 of the tristate buffer TB0 may be applied to the other tristate buffers TB1 and TB2, or the size ratio may be independently adjusted for the tristate buffers TB0, TB1, and TB2.

### Third Embodiment

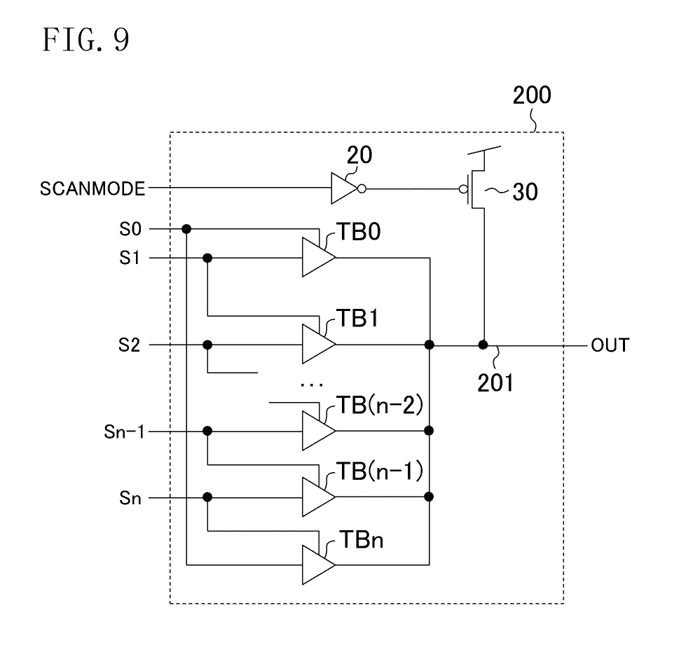

FIG. 9 illustrates an internal configuration of a fault detector 200 according to the third embodiment. This fault detector 200 receives (n+1) (where n is an integer greater than or equal to 3) control signals S0-Sn and a mode signal SCANMODE, and outputs a test enable signal OUT. The fault detector 200 includes tristate buffers TB0-TBn, an inverter 20, and a PMOS transistor 30.

The control signal S0 is input to a control terminal of the tristate buffer TB0 and to a data terminal of the tristate buffer TBn. The control signal Sk (where k=1, . . . , n) is input to a control terminal of the tristate buffer TBk and to a data terminal of the tristate buffer TB(k−1). The output terminals of the tristate buffers TB0-TBn are short-circuited at an output terminal 201 of the fault detector 200.

The mode signal SCANMODE is fixed to “0” during normal operation, and transitions to “1” only when a test is performed. The mode signal SCANMODE is input to the input terminal of the inverter 20. The output terminal of the inverter 20 is coupled to the gate of the PMOS transistor 30. The source of the PMOS transistor 30 is coupled to a power terminal, and the drain thereof is coupled to the output terminal 201. The PMOS transistor 30 is adjusted to have lower drive capability as compared to the transistors included in the tristate buffers TB0-TBn.

As described referring to the second embodiment, the size ratios (P/N ratios) between the PMOS transistors and the NMOS transistors of the respective tristate buffers TB0-TBn are adjusted so that a logical “1” is output as the output signal OUT when the output values of the tristate buffers TB0-TBn conflict with one another.

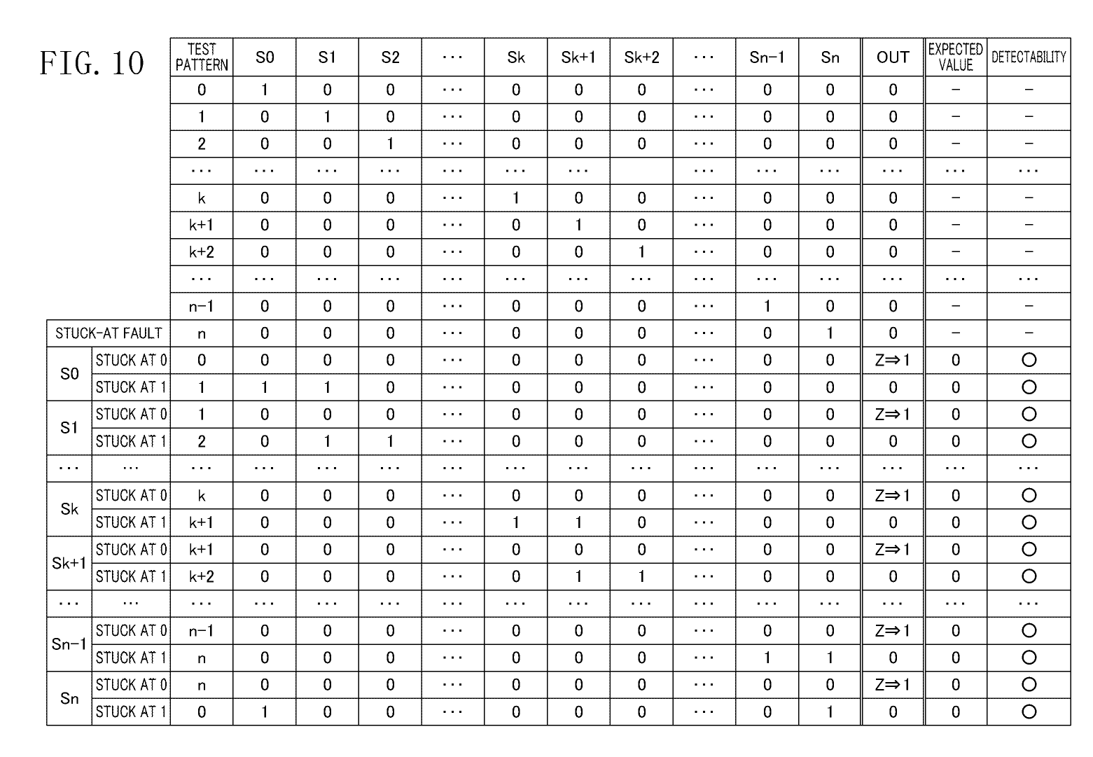

FIG. 10 is a table for detection of stuck-at faults at the control signals S0-Sn using such a circuit configuration. The table shows (n+1) patterns 0-n as the test patterns, and the corresponding expected values are all “0.”

Detection of a stuck-at-0 fault at the control signal Sk is performed by inputting the test pattern k. While only the input control signal Sk is a logical “1” during normal operation, an occurrence of a stuck-at-0 fault at the control signal Sk causes all of the control signals S0-Sn to be a logical “0,” and thus none of the tristate buffers TB0-TBn are activated, and the output terminal 201 is not driven. In this case, the PMOS transistor 30 fixes the value of the output terminal 201 at “1,” thereby causing the output signal OUT and the expected value of “0” to conflict with each other, and thus allowing a stuck-at-0 fault at the control signal Sk to be detected.

Meanwhile, detection of a stuck-at-1 fault at the control signal Sk is performed by inputting the test pattern (k+1) when 0≦k≦(n−1), and the test pattern 0 when k=n. In this case, two tristate buffers TBk and TB(k+1) or two tristate buffers TBn and TB0 are activated, and thus the output values conflict with each other. Accordingly, a logical “1” is output as the output signal OUT. This value is in conflict with the expected value of “0,” thereby allowing a stuck-at-1 fault at the control signal Sk to be detected.

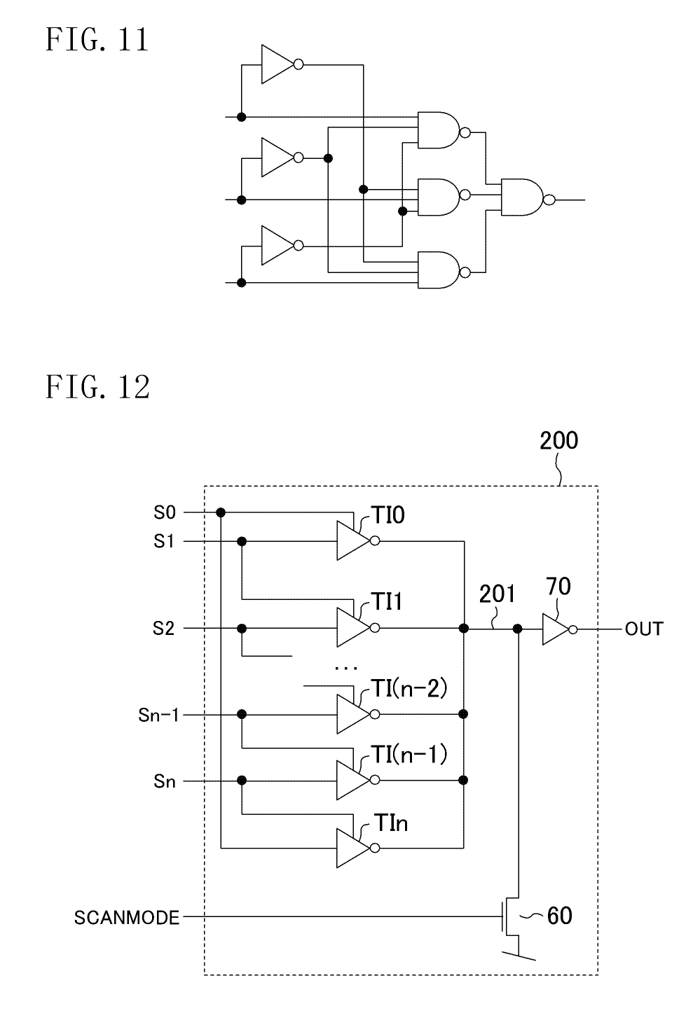

In addition, it can be understood that the fault detectors 200 of the first through third embodiments can be designed so as to be smaller in circuit area as compared to the fault detector suggested in Patent Document 1 listed above. FIG. 11 illustrates an example of a circuit having three inputs (see Patent Document 1). A comparison between the numbers of transistors included in this circuit and in the fault detector 200 of FIG. 2 produces a result as follows. The fault detector 200 of FIG. 2 uses three tristate gates (TB0, TB1, and TB2) each having eight transistors (in a case of the configuration of FIG. 5), an inverter (20) having two transistors, and a PMOS transistor (30), which total 27 transistors. Meanwhile, the circuit of FIG. 11 uses four NAND gates each having six transistors and three inverters each having two transistors, which total 30 transistors. As far as the number of transistors is concerned, the three-input fault detector 200 can theoretically achieve an about 10% reduction in circuit area with respect to the circuit suggested in Patent Document 1.

Moreover, extending the above discussion to an n-input fault detector, the fault detector 200 of FIG. 9 uses n tristate gates (TB0-TBn) each having eight transistors (in a case of the configuration of FIG. 5), an inverter (20) having two transistors, and a PMOS transistor (30), which total (8n+3) transistors. Meanwhile, the fault detector suggested in Patent Document 1 uses (n+1) n-input NAND gates each having 2n transistors and n inverters each having two transistor, which total (2n²+4n) transistors. Thus, a higher number of inputs n has a larger effect of reducing the circuit area. Note that a NAND gate having a high number of inputs are not practical for the NAND gates of FIG. 11; accordingly, in general, a six-input NAND gate is implemented as separate three-input NAND gates. In such a case, it is easily foreseeable that the number of transistors further increases, and the fault detectors 200 of the first through third embodiments each have an even larger effect of reducing the circuit area.

### Fourth Embodiment

FIG. 12 illustrates an internal configuration of a fault detector 200 according to the fourth embodiment. The fault detector 200 of this embodiment is the fault detector 200 of FIG. 1, but is implemented using tristate inverters. The fault detector 200 of FIG. 12 receives (n+1) control signals S0-Sn and a mode signal SCANMODE, and outputs a test enable signal OUT. The fault detector 200 includes tristate inverters TI0-TIn, an NMOS transistor 60, and an inverter 70.

The control signal S0 is input to a control terminal of the tristate inverter TI0 and to a data terminal of the tristate inverter TIn. The control signal Sk (where k=1, . . . , n) is input to a control terminal of the tristate inverter TIk and to a data terminal of the tristate inverter TI(k−1). The outputs of the tristate inverters TI0-TIn are short-circuited at an output terminal 201, and are input to the inverter 70.

The mode signal SCANMODE is fixed to “0” during normal operation, and transitions to “1” only when a test is performed. The mode signal SCANMODE is input to the gate of the NMOS transistor 60. The source of the NMOS transistor 60 is couple to a ground terminal, and the drain thereof is coupled to the output terminal 201. The NMOS transistor 60 is provided to fix the value at the output terminal 201 when none of the tristate inverters TI0-TIn drive the output terminal 201. Assume that the NMOS transistor 60 is adjusted to have relatively low drive capability, and has no effects on the output data of the tristate inverters TI0-TIn. Moreover, another inverter may be provided in an output portion as necessary to adjust the logic.

Also in this embodiment, a stuck-at fault at the control signals S0-Sn can be detected in a similar manner in which the table of FIG. 10 is used.

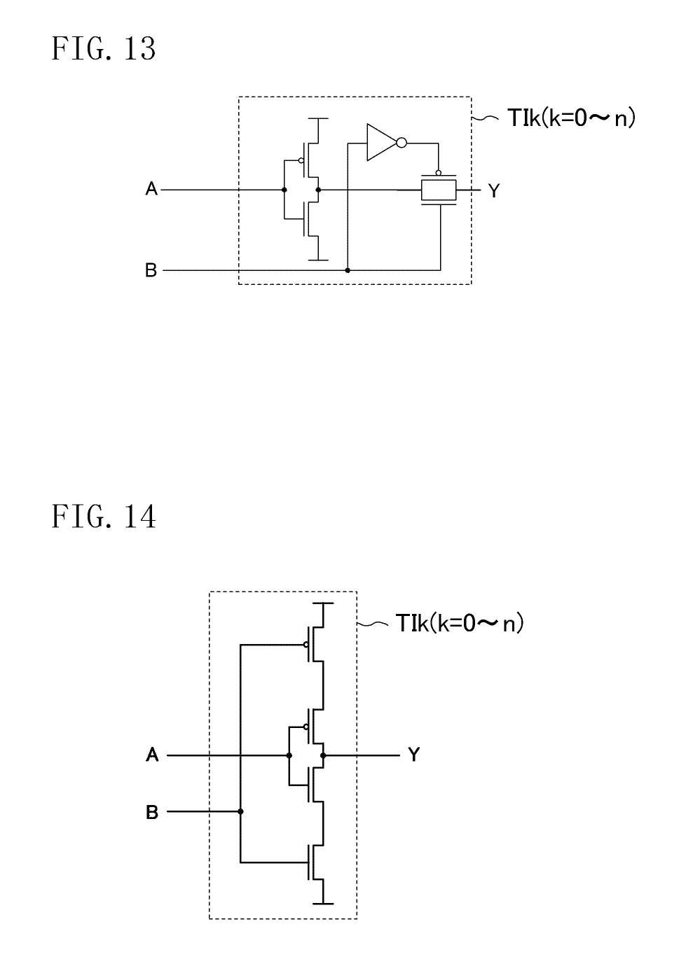

FIGS. 13 and 14 each illustrate an example of an internal configuration of the tristate inverter TIk (where k=0, . . . , n) included in the fault detector 200. The internal configurations are illustrated merely by way of example, and any element which can transition between three states, and whose output is inverted with respect to the input thereof can be used to implement the fault detector 200.

### Fifth Embodiment

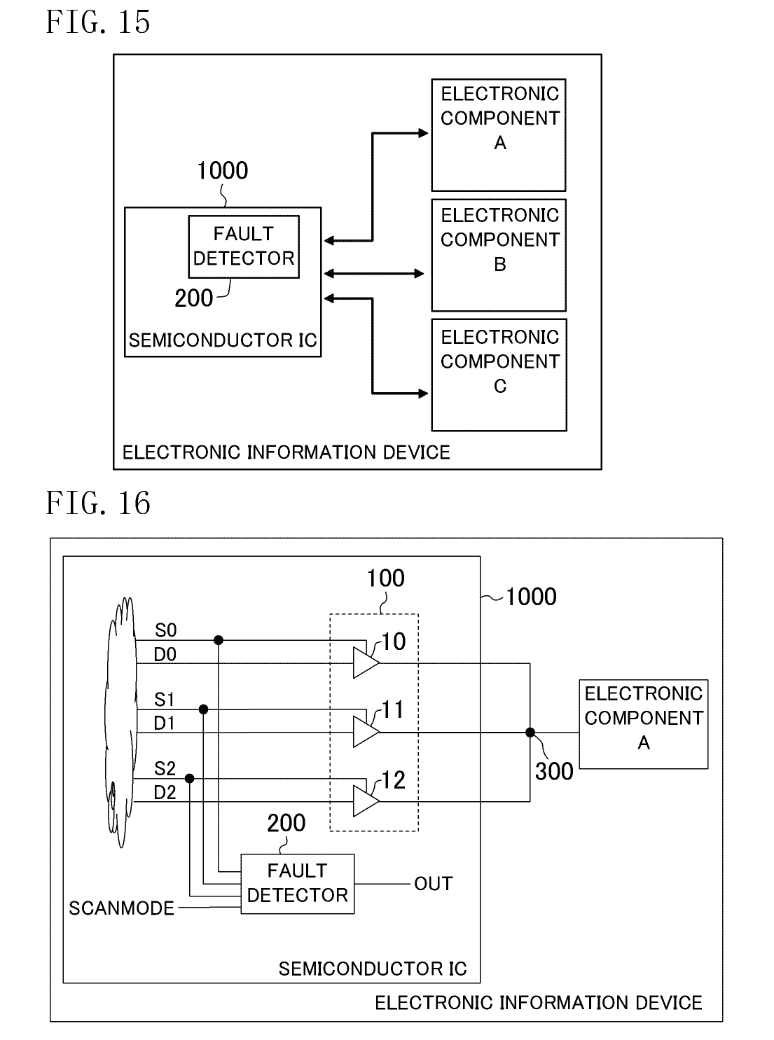

A configuration of an electronic information device according to the fifth embodiment is shown in FIG. 15. The electronic information device includes a semiconductor IC 1000 and electronic components A, B, and C. The semiconductor IC 1000 includes one of the fault detectors 200 according to the first through fourth embodiments. The semiconductor IC 1000 communicates with each of the electronic components A, B, and C, and performs required processing.

FIG. 16 illustrates a detailed configuration of the connection between the semiconductor IC 1000 and the electronic component A. The semiconductor IC 1000 and the electronic component A transmit and receive signals to/from each other. As an example, a configuration of bus signal lines using tristate gates will be discussed below.

The semiconductor IC 1000 outputs internally-processed signals through tristate gates 10, 11, and 12 to the outside world as a plurality of signals D0, D1, and D2. Control signals S0, S1, and S2 of the tristate bus are controlled so that one of the tristate gates drives the output. The plurality of signals D0, D1, and D2 output from the semiconductor IC 1000 are short-circuited on a substrate 300 of the electronic information device, and are input to an input terminal of the electronic component A. With this configuration, flexibility of designing on a substrate of the electronic information device, and high-speed transmission between the electronic components are achievable.

Providing the semiconductor IC 1000 with one of the fault detectors 200 according to the first through fourth embodiments allows detection of a fault at the control signals S0, S1, and S2 of the tristate gates 10, 11, and 12 forming the output bus lines of the semiconductor IC 1000.

It should be understood that the present invention is not limited to the particular embodiments disclosed above, and may be embodied in various forms without departing from its spirit or essential characteristics. The described embodiments are to be considered in all respects only as illustrated and not restrictive. The scope of the invention is, therefore, indicated by the appended claims rather than by the foregoing description. All changes and modifications which come within the meaning and range of equivalency of the claims are to be embraced within their scope.

The semiconductor ICs and the electric information device according to the present invention use technologies to achieve both high-speed operation and high quality at the same time, and are useful for components used in digital home appliances etc., and in addition to digital home appliances, in a wide range of products requiring high performance semiconductor ICs such as mobile phones and car navigation systems.

What is claimed is:

1. A semiconductor integrated circuit comprising:
a fault detector configured to receive control signals which are input to control terminals of corresponding tristate gates, and a test enable signal, and configured to invert an output signal when one of the control signals is inverted due to a fault at the one of the control signals,
wherein
the fault detector includes a set of tristate gates different from the corresponding tristate gates.

2. The semiconductor integrated circuit of claim 1, wherein
the fault detector includes the n tristate gates, where n is an integer greater than or equal to 3, configured to respectively receive the n control signals,
a control terminal of a k-th one, where 0≦k≦n, of the set of the tristate gates is configured to receive a k-th one of the control signals,
a data terminal of the k-th one, where 0≦k≦(n−1), of the set of the tristate gates is configured to receive a (k+1)-th one of the control signals,
a data terminal of the n-th one of the set of the tristate gates is configured to receive a 0-th one of the control signals,
outputs of the n tristate gates are coupled at a same node, and
a transistor configured to pull up or pull down the output signal under a predetermined condition is coupled to the same node.

3. The semiconductor integrated circuit of claim 2, wherein
the fault detector is configured to pull up the output signal to 1 or to pull down the output signal to 0 when a plurality of the tristate gates drive the same node.

4. The semiconductor integrated circuit of claim 3, wherein
in the fault detector, a size of an NMOS transistor which drives the same node is larger than a size of a PMOS transistor which drives the same node, among transistors included in the set of tristate gates.

5. The semiconductor integrated circuit of claim 3, wherein
in the fault detector, when a PMOS transistor and an NMOS transistor included in the plurality of the tristate gates simultaneously drive the same node, a size ratio between the PMOS transistor and the NMOS transistor is adjusted so that drive operation by the PMOS transistor is dominant.

6. The semiconductor integrated circuit of claim 1, wherein
each of the set of the tristate gates is formed by a tristate buffer.

7. The semiconductor integrated circuit of claim 1, wherein
each of the set of the tristate gates is formed by a tristate inverter.

8. An electronic information device, comprising:
the semiconductor integrated circuit of claim 1; and
an electronic component configured to communicate with the semiconductor integrated circuit,
wherein
the semiconductor integrated circuit includes a communication circuit including n tristate gates, where n is an integer greater than or equal to 3,
the communication circuit communicates with the electronic component,
control signals of the tristate gates are input to the fault detector, and
signals of the communication circuit are short-circuited outside the semiconductor integrated circuit, and are input to the electronic component.
